(19) United States
(12) Patent Application Publication
(10) Pub. No.: US 2025/0120073 A1
(43) Pub. Date: Apr. 10, 2025

(54) INTEGRATED CIRCUIT DEVICE

(71) Applicant: Samsung Electronics Co., Ltd., Suwon-si (KR)

(72) Inventors: Sunghoon Bae, Suwon-si (KR); Seungbo Ko, Suwon-si (KR); Euna Kim, Suwon-si (KR)

(21) Appl. No.: 18/906,420

(22) Filed: Oct. 4, 2024

(30) Foreign Application Priority Data
Oct. 6, 2023 (KR) 10-2023-0133694

(51) Int. Cl. H10B 12/00

(52) U.S. Cl. CPC H10B 12/50; H10B 12/482

(57) ABSTRACT

Provided is an integrated circuit device including a substrate having a cell array area, a peripheral circuit area surrounding the cell array area, and an interface area between the cell array area and the peripheral circuit area, a plurality of bit lines extending in a first horizontal direction on the cell array area and the interface area and placed parallel to each other in a second horizontal direction perpendicular to the first horizontal direction, insulating capping patterns extending in the first horizontal direction on the bit lines, a plurality of contact plugs vertically connected to the bit lines, respectively, in the interface area, and a plurality of contact pads disposed on the plurality of contact plugs, respectively, wherein the contact plugs are spaced apart from centers of the bit lines in the second horizontal direction at a certain gap in the second horizontal direction.

### CROSS-REFERENCE TO RELATED APPLICATION

This application is based on and claims priority under 35 U.S.C. § 119 to Korean Patent Application No. 10-2023-0133694, filed on Oct. 6, 2023, in the Korean Intellectual Property Office, the disclosure of which is incorporated by reference herein in its entirety.

### BACKGROUND

The inventive concept relates to an integrated circuit device, and more particularly, to an integrated circuit device including bit lines.

In accordance with the rapid development of the electronics industry and demands of users, electronic devices are becoming smaller and lighter. Accordingly, semiconductor devices with a high degree of integration used in electronic devices are required, and design rules for the configurations of semiconductor devices are decreasing.

### SUMMARY

Aspects of the inventive concept provides an integrated circuit device in which a central axis of a contact plug in an interface area is different from a central axis of a bit line.

According to an aspect of the inventive concept, there is provided an integrated circuit device including a substrate having a cell array area, a peripheral circuit area surrounding the cell array area, and an interface area between the cell array area and the peripheral circuit area, a plurality of bit lines extending in a first horizontal direction on the cell array area and the interface area and placed parallel to each other in a second horizontal direction perpendicular to the first horizontal direction, insulating capping patterns extending in the first horizontal direction on the bit lines, a plurality of contact plugs vertically connected to the bit lines, respectively, in the interface area, and a plurality of contact pads disposed on the plurality of contact plugs, respectively, wherein the contact plugs are spaced apart from centers of the bit lines in the second horizontal direction at a certain gap in the second horizontal direction.

According to another aspect of the inventive concept, there is provided an integrated circuit device including a substrate having a cell array area, a peripheral circuit area surrounding the cell array area, and an interface area between the cell array area and the peripheral circuit area, a plurality of bit lines extending in a first horizontal direction on the cell array area and the interface area and placed parallel to each other in a second horizontal direction perpendicular to the first horizontal direction, insulating capping patterns extending in the first horizontal direction on the bit lines, a plurality of contact plugs vertically connected to the bit lines, respectively, in the interface area, and a plurality of contact pads disposed on the plurality of contact plugs, respectively, wherein a sidewall of the contact plug in the first horizontal direction protrudes from a sidewall of the bit line in the first horizontal direction.

According to another aspect of the inventive concept, there is provided an integrated circuit device including a substrate having a cell array area, a peripheral circuit area surrounding the cell array area, and an interface area between the cell array area and the peripheral circuit area, a plurality of bit lines extending in a first horizontal direction on the cell array area and the interface area and arranged parallel to each other in a second horizontal direction perpendicular to the first horizontal direction, the bit lines each including a bit line head, a width of which in the second horizontal direction increases in the interface area, insulating capping patterns extending in the first horizontal direction on the bit lines, a plurality of contact plugs vertically connected to the plurality of bit lines in the interface area, respectively, a plurality of contact pads placed on the plurality of contact plugs and extending in the first horizontal direction to the peripheral circuit area, and insulating spacers each covering a sidewall of the bit line head and dummy landing pads each vertically positioned between the insulating spacers, wherein the contact plug is spaced apart from the center of the bit line head in the second horizontal direction at a certain gap in the second horizontal direction.

### BRIEF DESCRIPTION OF THE DRAWINGS

Embodiments will be more clearly understood from the following detailed description taken in conjunction with the accompanying drawings in which:

FIG. 1 is a layout diagram of an integrated circuit device according to an embodiment;

FIG. 2 is an enlarged layout diagram of portion A of FIG. 1 according to an embodiment;

FIG. 3A is a cross-sectional view, showing some components, taken along line Y1-Y1′in FIG. 2;

FIG. 3B is a cross-sectional view, showing some components, taken along line Y2-Y2′ in FIG. 2;

FIG. 4A is an enlarged cross-sectional view of a portion indicated as “EX1” in FIG. 2 according to an embodiment;

FIG. 4B is a cross-sectional view, showing some components, taken along line I-I′ of FIG. 2 according to an embodiment;

FIG. 5A is an enlarged cross-sectional view of a portion indicated by “EX1” in FIG. 2 according to an embodiment;

FIG. 5B is a cross-sectional view, showing some components, taken along line I-I′ of FIG. 2 according to an embodiment;

FIGS. 6A and 6B are enlarged cross-sectional views of a portion indicated by “EX1” in FIG. 2 according to an embodiment;

FIGS. 7A to 7D are cross-sectional views, shown according to a process sequence, of a method of manufacturing an integrated circuit device according to an embodiment, and cross-sectional views, shown according to a process sequence, of portions corresponding to a cross-section taken along line I-I′ of FIG. 2;

FIG. 8A is an enlarged layout diagram of portion A of FIG. 1 according to an embodiment;

FIG. 8B is a cross-sectional view, showing some components, taken along line II-II′ of FIG. 8A; and

FIG. 8C is a cross-sectional view, showing some components, taken along line III-III′ of FIG. 8A.

### DETAILED DESCRIPTION OF THE EMBODIMENTS

Hereinafter, embodiments are described in detail with reference to the attached drawings. The same reference numerals are used for the same components in the drawings, and duplicate descriptions thereof are omitted.

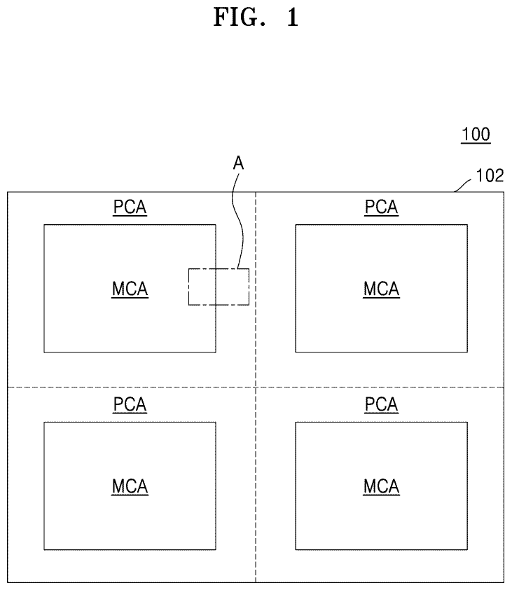

FIG. 1 is a layout diagram of an integrated circuit device according to an embodiment.

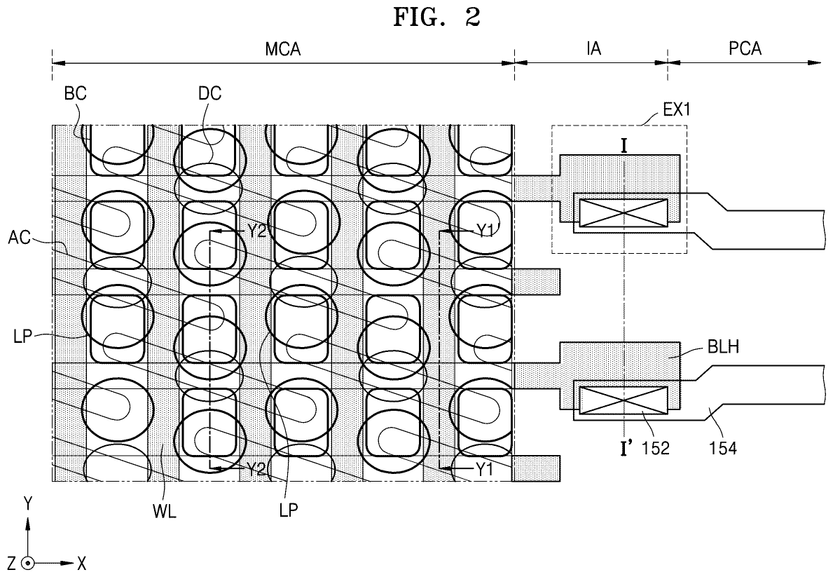

FIG. 2 is an enlarged layout diagram of portion A of FIG. 1 according to an embodiment.

Referring to FIGS. 1 and 2, an integrated circuit device 100 of the inventive concept may include a substrate 102 including cell array areas MCA and peripheral circuit areas PCA. The substrate 102 may include, for example, a semiconductor element such as Si, Ge, etc., or at least one compound semiconductor selected from SiGe, SiC, GaAs, InAs, and InP. The substrate 102 may include a conductive area, for example, a well doped with a dopant, or a structure doped with a dopant.

The cell array area MCA may be a memory cell area of a dynamic random access memory (DRAM) device, and the peripheral circuit area PCA may be a core area or a peripheral circuit area of the DRAM device. For example, the cell array area MCA may include a plurality of unit memory cells having transistors and capacitors. The peripheral circuit area PCA may be an area where peripheral circuits required to drive memory cells in the cell array area MCA are arranged, and may include capacitors. The peripheral circuit area PCA may include peripheral circuit transistors for transmitting signals and/or power to the memory cell array included in the cell array area MCA. In some embodiments, the peripheral circuit transistors may form various circuits such as a command decoder, a control logic, an address buffer, a row decoder, a column decoder, a sense amplifier, and a data input/output circuit.

An interface area IA may be positioned between the cell array area MCA and the peripheral circuit area PCA. A plurality of conductive lines for electrical connection between the cell array area MCA and the peripheral circuit area PCA, and insulating structures for insulation between the cell array area MCA and the peripheral circuit area PCA may be arranged in the interface area IA. In some embodiments, the interface area IA does not include any transistors.

The integrated circuit device 100 may include a plurality of active areas AC extending on the X-Y plane in a diagonal direction with respect to a first horizontal direction (X direction) and a second horizontal direction (Y direction) orthogonal to each other. A plurality of word lines WL may extend parallel to each other in the second horizontal direction (Y direction) across the plurality of active areas AC. Each of the plurality of word lines WL may have a substantially constant width in the first horizontal direction (X direction) along the second horizontal direction. That is, they have a constant width on the X direction as one traverses along the Y direction. In some embodiments, the plurality of word lines WL may be buried in the substrate 102, and the integrated circuit device 100 may include a buried channel array transistor (BCAT) structure, but are not limited thereto.

A plurality of bit lines BL may extend in the first horizontal direction (X direction) to be parallel to each other, and may cross the plurality of word lines WL. The plurality of bit lines BL may be respectively connected to the plurality of active areas AC of the unit memory cells through direct contacts DC.

A plurality of buried contacts BC may be arranged between two adjacent bit lines BL among the plurality of bit lines BL. A plurality of conductive landing pads LP may be arranged on the plurality of buried contacts BC. The plurality of buried contacts BC and the plurality of conductive landing pads LP may connect lower electrodes (not shown) of capacitors formed on top of the plurality of bit lines BL to the active areas AC. The plurality of conductive landing pads LP may overlap at least portions of the buried contacts BC, respectively.

As used herein, “conductive,” “conductivity,” “isolate,” “isolation,” “insulative,” and “insulating” refer to “electrically conductive,” “electrical conductivity,” “electrically isolate,” “electrical isolation,” “electrically insulative,” and “electrically insulating”, unless the context clearly indicates otherwise.

In some embodiments, contact plugs 152 and contact pads 154 may be positioned in the interface area IA of the integrated circuit device 100. The contact plugs 152 and the contact pads 154 may include or be formed of tungsten (W), but are not limited thereto.

The contact plug 152 may be connected to one end portion of the bit line BL in the interface area IA. Specifically, the contact plug 152 may be connected to a bit line head BLH. The bit line head BLH may be formed at one end portion of the bit line BL in the interface area IA. The bit line BL in the cell array area MCA and the bit line head BLH in the interface area IA may be formed simultaneously. The bit line BL and the bit line head BLH may be formed simultaneously using a hard mask patterned by an exposure process using extreme ultraviolet (EUV) light. Therefore, each bit line BL and corresponding bit line head BLH may be a continuous structure formed of the same material without a boundary interface therebetween.

From a plan view, the bit line head BLH may have a hammer-head shape. That is, the width of the one end portion (i.e., the bit line head BLH) in the second horizontal direction (Y direction) may be greater than the width of the other portion of the bit line BL in the second horizontal direction (Y direction). For example, the width of the bit line head BLH in the second horizontal direction (Y direction) may be about three times greater than the width of the bit line BL in the second horizontal direction (Y direction) in the cell array area MCA, but is not limited thereto. For example, the width of the bit line BL in the second horizontal direction (Y direction) may be about 10 nm in the cell array area MCA, and the width of the bit line head BLH in the second horizontal direction (Y direction) may be about 30 nm. The bit line heads BLH may be alternately formed at alternating end portions of adjacent bit lines BL of the plurality of bit lines BL, but are not limited thereto.

The contact plug 152 may be spaced apart from the center of the bit line head BLH in the second horizontal direction (Y direction) by a certain gap in the second horizontal direction (Y direction). The contact plug 152 may be spaced apart from the center of the bit line head BLH in the second horizontal direction (Y direction) by a gap of about 5 nm in the second horizontal direction (Y direction).

The contact plug 152 may be electrically connected to one end of the contact pad 154. The contact pad 154 may extend from the contact plug 152 to the peripheral circuit area PCA in the first horizontal direction (X direction). The contact plug 152 may electrically connect the bit line BL in the cell array area MCA to the contact pad 154 in the interface area IA, which continues into the peripheral circuit area PCA.

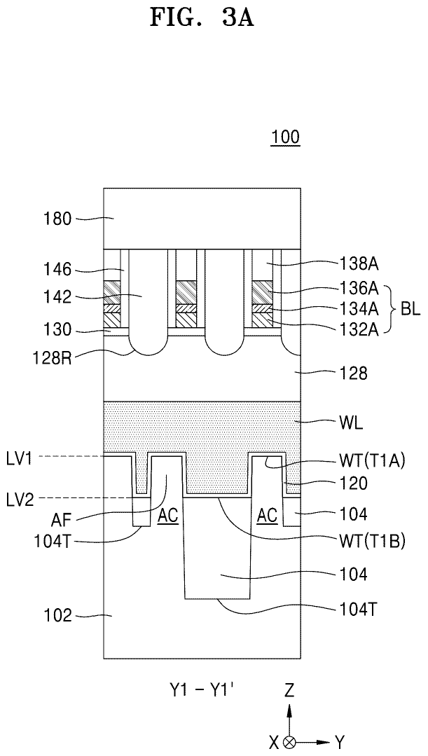

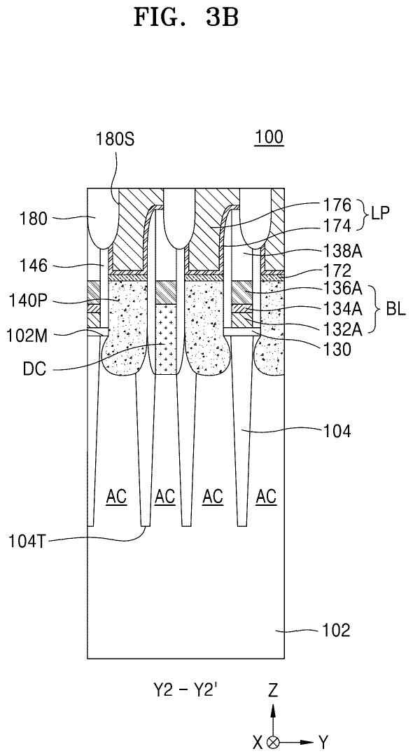

FIG. 3A is a cross-sectional view, showing some components, taken along line Y1-Y1′in FIG. 2.

FIG. 3B is a cross-sectional view, showing some components, taken along line Y2-Y2′ in FIG. 2.

Referring to FIGS. 3A and 3B, the integrated circuit device 100 may include a substrate 102 where device isolation trenches 104T are formed. The device isolation trench 104T may be filled with a device isolation film 104. The plurality of active areas AC may be defined by the device isolation trenches 104T and the device isolation films 104 in the substrate 102.

The device isolation films 104 may surround the plurality of active areas AC on the substrate 102. The device isolation films 104 may include a silicon oxide film, a silicon nitride film, or a combination thereof. The vertical level of the bottom surfaces of the device isolation trenches 104T may vary depending on the width of the device isolation trenches 104T in the horizontal direction. As the width of the device isolation trenches 104T in the horizontal direction increases, the vertical level of the bottom surfaces of the device isolation trenches 104T may be further away from a main surface 102M of the substrate 102. The term “vertical level” used herein refers to a height in the vertical direction (Z direction or −Z direction) from the main surface 102M of the substrate 102.

A plurality of word line trenches WT in the substrate 102 may be formed to be parallel to each other in the first horizontal direction (X direction). The plurality of word line trenches WT may each have a line shape extending longitudinally in the second horizontal direction (Y direction) across the plurality of active areas AC and the device isolation films 104. The interior of each of the plurality of word line trenches WT may be filled with a gate dielectric film 120, a word line WL, and an insulating capping pattern 128.

As shown in FIG. 3A, in each of the plurality of word line trenches WT, the vertical level of the bottom surfaces of the portions on the plurality of active areas AC may be higher than the vertical level of the bottom surfaces of the portions on the device isolation films 104. Accordingly, the bottom profile of the plurality of word line trenches WT may have an uneven shape, and the bottom surfaces of the word lines WL may have an uneven shape corresponding to the bottom profile of the word line trenches WT. A plurality of fin areas AF protruding upward in the vertical direction (Z direction) from the bottoms of the word lines WL toward the word lines WL corresponding to the bottom profile of the word line trenches WT may be formed in the plurality of active areas AC.

The plurality of word line trenches WT may include a first trench portion TIA positioned in the substrate 102 and having a lowest surface at a first vertical level LV1, and a second trench portion T1B positioned in the device isolation film 104 and having a lowest surface at a second vertical level LV2 lower than the first vertical level LV1.

The gate dielectric film 120 may conformally cover inner surfaces of the word line trenches WT to contact the plurality of active areas AC and the device isolation film 104. The gate dielectric film 120 may include a silicon oxide layer, for example, a SiO2 layer. The gate dielectric film 120 may have a thickness of about 10 nm to about 30 nm, but is not limited thereto.

Each of the plurality of word lines WL may extend longitudinally in the second horizontal direction (Y direction) while filling a lower space that is a part of the word line trench WT on the gate dielectric film 120. The insulating capping pattern 128 may extend longitudinally in the second horizontal direction (Y direction) while filling an upper space that is another part of the word line trench WT on each of the plurality of word lines WL.

The insulating capping pattern 128 may fill the remaining space of the word line trench WT on the word line WL. In some embodiments, the insulating capping pattern 128 may include a silicon nitride film, a silicon oxynitride film, a silicon oxide film, or a combination thereof. For example, the insulating capping pattern 128 may include a silicon nitride film. In another example, the insulating capping pattern 128 may include a silicon nitride film filling an upper space of the word line trench WT.

A plurality of source/drain regions may be arranged at both sides of the plurality of word lines WL in the plurality of active areas AC. Each of the plurality of source/drain regions may include an impurity region containing impurity ions implanted into the substrate 102.

The main surface 102M of the substrate 102, the device isolation film 104, and the insulating capping pattern 128 may be covered by a buffer insulating film 130. The buffer insulating film 130 may include an oxide film, a nitride film, or a combination thereof. As shown in FIG. 3B, the plurality of direct contacts DC may be disposed on a portion of each of the plurality of active areas AC. The plurality of bit lines BL may extend longitudinally in the first horizontal direction (X direction) on the buffer insulating film 130 and the plurality of direct contacts DC. The plurality of bit lines BL may be covered by a plurality of insulating capping patterns 138A.

A plurality of conductive cell plugs 140P and a plurality of insulating fences 142 may be alternately arranged in a row one-by-one in the first horizontal direction (X direction) between a pair of adjacent bit lines BL among the plurality of bit lines BL. The plurality of insulating fences 142 may fill a plurality of recesses 128R formed in the top surface of the insulating capping pattern 128 and may be arranged one-by-one between each of the plurality of conductive cell plugs 140P. In the first horizontal direction (X direction), both sidewalls of each of the plurality of conductive cell plugs 140P may be covered by the plurality of insulating fences 142. The plurality of conductive cell plugs 140P arranged in a row in the first horizontal direction (X direction) may be insulated from each other by the plurality of insulating fences 142. The plurality of conductive cell plugs 140P may form the plurality of buried contacts BC illustrated in FIG. 2.

Each of the plurality of bit lines BL may be connected to the active area AC through the direct contact DC. One direct contact DC and a pair of conductive cell plugs 140P facing each other with the one direct contact DC positioned therebetween may be connected to different active areas AC among the plurality of active areas AC. In some embodiments, the direct contacts DC may include Si, Ge, W, WN, Co, Ni, Al, Mo, Ru, Ti, TiN, Ta, TaN, Cu, or a combination thereof. For example, the direct contacts DC may include or be formed of an epitaxial silicon layer.

The plurality of bit lines BL may include a first lower conductive layer 132A, a first intermediate conductive layer 134A, and a first upper conductive layer 136A which are sequentially formed on the substrate 102. The top surface of the first lower conductive layer 132A and the top surface of the direct contact DC may extend on the same plane. In FIGS. 3A and 3B, the plurality of bit lines BLs are illustrated as having a triple-layer structure including the first lower conductive layer 132A, the first intermediate conductive layer 134A, and the first upper conductive layer 136A, but are not limited thereto. For example, the plurality of bit lines BL may be formed in a single-layer structure, a double-layer structure, or a multi-layer structure of four or more layers.

In some embodiments, the first lower conductive layer 132A may include conductive polysilicon. The first intermediate conductive layer 134A and the first upper conductive layer 136A may include TIN, TiSiN, W, tungsten silicide, or a combination thereof. For example, the first intermediate conductive layer 134A may include TiN and/or TiSiN, and the first upper conductive layer 136A may include W. The insulating capping pattern 138A may include a silicon nitride film.

The plurality of conductive cell plugs 140P may have a column shape extending in the vertical direction (Z direction) along a space between each of the plurality of bit lines BL on the substrate 102. The bottom surface of each of the plurality of conductive cell plugs 140P may be in contact with the active area AC. A portion of each of the plurality of conductive cell plugs 140P may be at a lower level than the main surface 102M of the substrate 102. The plurality of conductive cell plugs 140P may include doped polysilicon, metal, conductive metal nitride, or a combination thereof.

Each of the plurality of insulating fences 142 may have a column shape extending in the vertical direction (Z direction) between each of the plurality of bit lines BL. The plurality of insulating fences 142 may include a silicon nitride film.

Both sidewalls of each of the plurality of bit lines BL, the plurality of insulating capping patterns 138A, and the plurality of direct contacts DC may be covered by a plurality of insulating spacers 146. The plurality of insulating spacers 146 may extend long in the first horizontal direction (X direction) parallel to the plurality of bit lines BL on both sidewalls of the plurality of bit lines BL. The plurality of insulating spacers 146 may include an oxide film, a nitride film, an air spacer, or a combination thereof. As used herein, the term “air” may refer to the atmosphere or a space containing other gases that may exist during the manufacturing process.

Each of the plurality of conductive cell plugs 140P may be spaced apart from the bit line BL in the second horizontal direction (Y direction) with the insulating spacer 146 positioned therebetween. Each of the plurality of insulating fences 142 may be spaced apart from the bit line BL in the second horizontal direction (Y direction) with the insulating spacer 146 positioned therebetween.

Metal silicide films 172 and conductive landing pads LP may be sequentially formed on the conductive cell plugs 140P. The metal silicide films 172 and the conductive landing pads LP may be arranged to vertically overlap the conductive cell plugs 140P. Each of the plurality of metal silicide films 172 may be positioned between the conductive cell plug 140P and the conductive landing pad LP and may be spaced apart from the bit line BL with the insulating spacer 146 positioned therebetween. The metal silicide films 172 may include cobalt silicide, nickel silicide, or manganese silicide.

Each of the plurality of conductive landing pads LP may be connected to the conductive cell plug 140P through the metal silicide film 172. The plurality of conductive landing pads LP may extend from a space between each of the plurality of insulating capping patterns 138A to an upper space of each of the plurality of insulating capping patterns 138A to vertically overlap a portion of the plurality of bit lines BL. Each of the plurality of conductive landing pads LP may include a conductive barrier film 174 and a conductive pad layer 176. The conductive barrier film 174 may include Ti, TiN, or a combination thereof. The conductive pad layer 176 may include metal, metal nitride, conductive polysilicon, or a combination thereof. For example, the conductive pad layer 176 may include W.

The plurality of conductive landing pads LP may have a plurality of island-type pattern shapes from a plan view. The plurality of conductive landing pads LP may be electrically insulated from each other by insulating films 180 filling insulating spaces 180S around the plurality of conductive landing pads LP. The insulating films 180 may include a silicon nitride film, a silicon oxide film, or a combination thereof.

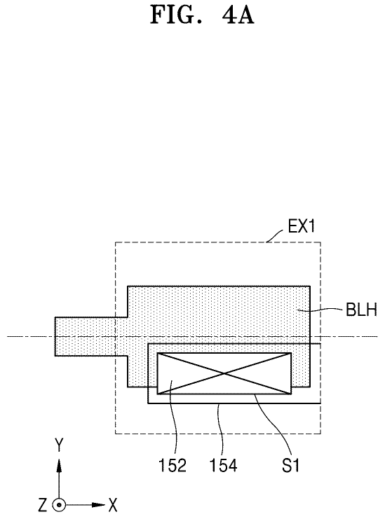

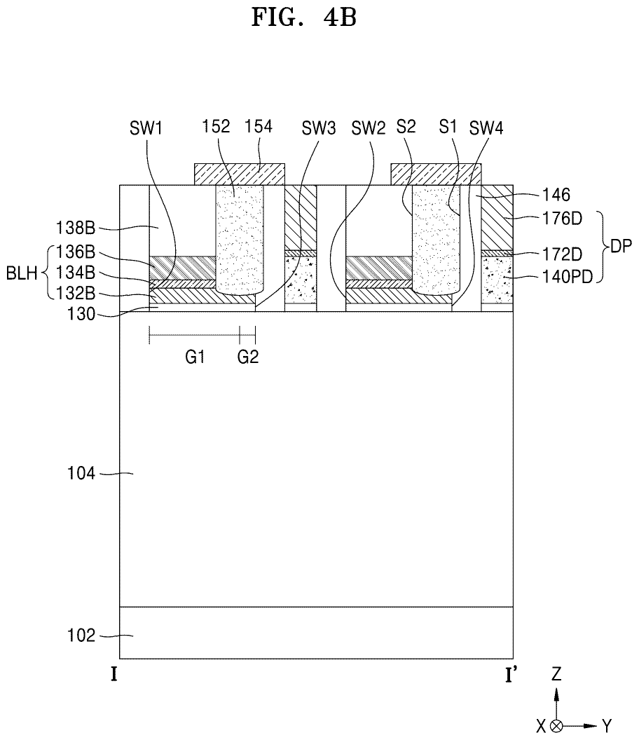

FIG. 4A is an enlarged cross-sectional view of a portion indicated as “EX1” in FIG. 2 according to an embodiment.

FIG. 4B is a cross-sectional view, showing some components, taken along line I-I′ of FIG. 2 according to an embodiment.

Referring to FIGS. 4A and 4B, the device isolation film 104 may be defined on the substrate 102, and the device isolation film 104 may be covered by the buffer insulating film 130. The buffer insulating films 130 may include an oxide film, a nitride film, or a combination thereof.

In some embodiments, the plurality of bit line heads BLH may be disposed on the buffer insulating film 130. The plurality of bit line heads BLH may be parallel to each other and may be arranged repeatedly in the second horizontal direction (Y direction). The plurality of bit line heads BLH may extend in the first horizontal direction (X direction).

Each of the plurality of bit line heads BLH may include a second lower conductive layer 132B, a second intermediate conductive layer 134B, and a second upper conductive layer 136B which are sequentially formed on the substrate 102. The second lower conductive layer 132B, the second intermediate conductive layer 134B, and the second upper conductive layer 136B of the bit line head BLH may be substantially and respectively the same as the first lower conductive layer 132A, the first intermediate conductive layer 134A, and the first upper conductive layer 136A of the bit line BL in the cell array area MCA.

In FIG. 4B, the plurality of bit line heads BLH are illustrated as having a triple-layer structure including the second lower conductive layer 132B, the second intermediate conductive layer 134B, and the second upper conductive layer 136B, but are not limited thereto. For example, the bit line heads BLH may be formed in a single-layer structure, a double-layer structure, or a multi-layer structure of four or more layers.

In some embodiments, the second lower conductive layer 132B may include conductive polysilicon. The second intermediate conductive layer 134B and the second upper conductive layer 136B may include TiN, TiSiN, W, tungsten silicide, or a combination thereof. For example, the second intermediate conductive layer 134B may include TiN and/or TiSiN, and the second upper conductive layer 136B may include W. An insulating capping pattern 138B may be formed on the second upper conductive layer 136B. The insulating capping pattern 138B may include a silicon nitride film.

Sidewalls of the plurality of bit line heads BLH may be covered by the plurality of insulating spacers 146, respectively. The plurality of insulating spacers 146 may extend longitudinally in the first horizontal direction (X direction) parallel to the plurality of bit line heads BLH on both sidewalls of the plurality of bit heads BLH. The plurality of insulating spacers 146 may include an oxide film, a nitride film, an air spacer, or a combination thereof.

A plurality of dummy patterns DP may be positioned between a plurality of insulating spacers 146. Each of the plurality of dummy patterns DP may be spaced apart from the bit line head BLH in the second horizontal direction (Y direction) with the insulating spacer 146 positioned therebetween. Each of the plurality of dummy patterns DP may include conductive dummy plugs 140PD, dummy metal silicide films 172D, and dummy landing pads 176D. Each of the conductive dummy plugs 140PD, the dummy metal silicide films 172D, and the dummy landing pads 176D is conductive. Accordingly, each of the plurality of dummy patterns DP is electrically conductive (i.e., has electrical conductivity), though the dummy patterns are electrically isolated from other components having substantial function of the integrated circuit's electrical operation, unless context clearly indicates otherwise.

The plurality of conductive dummy plugs 140PD may be positioned between the plurality of insulating spacers 146. Each of the plurality of conductive dummy plugs 140PD may be spaced apart from the bit line head BLH in the second horizontal direction (Y direction) with the insulating spacer 146 positioned therebetween.

The plurality of conductive dummy plugs 140PD may have a column shape extending in the vertical direction (Z direction) along a space between each of the plurality of insulating spacers 146 on the substrate 102. The plurality of conductive dummy plugs 140PD may include doped polysilicon, metal, conductive metal nitride, or a combination thereof.

The dummy metal silicide films 172D and dummy landing pads 176D may be sequentially formed on the plurality of conductive dummy plugs 140PD. The dummy metal silicide films 172D and the dummy landing pads 176D may be arranged to vertically overlap the conductive dummy plugs 140PD. Each of the plurality of dummy metal silicide films 172D may be positioned between the conductive dummy plug 140PD and the dummy landing pad 176D and may be spaced apart from the bit line BL with the insulating spacer 146 positioned therebetween. The dummy metal silicide films 172D may be or include cobalt silicide, nickel silicide, or manganese silicide. The dummy landing pads 176D may be or include metal, metal nitride, conductive polysilicon, or a combination thereof.

As used herein, the term “dummy” is used to refer to a component that has the same or similar structure and shape as other components but does not have any substantial function and exists only as a pattern or structure in the device. Unless context indicates otherwise, it should be appreciated that the dummy patterns are electrically isolated from other components having substantial function of the integrated circuit's electrical operation.

In some embodiments, an insulating dummy pattern may be positioned in the space between each of the plurality of insulating spacers 146, instead of the plurality of conductive dummy plugs 140PD, the dummy metal silicide films 172D, and the dummy landing pads 176D. The insulating dummy pattern may include an oxide film, a nitride film, or a combination thereof.

In some embodiments, the contact plug 152 may contact a portion of the bit line head BLH. The contact plug 152 may have a column shape extending in the vertical direction (Z direction) so as to contact a portion of the bit line head BLH. The width of the contact plug 152 in the second horizontal direction (Y direction) may be less than the width of the bit line head BLH in the second horizontal direction (Y direction). The contact plug 152 may penetrate the insulating capping pattern 138B. The contact plug 152 may include or be formed of a metal-containing material such as W, but is not limited thereto.

The contact plug 152 may be spaced apart from the center of the bit line head BLH in the second horizontal direction (Y direction) by a certain gap in the second horizontal direction (Y direction). For example, the contact plug 152 may be spaced apart from the center of the bit line head BLH in the second horizontal direction (Y direction) by a gap of about 5 nm in the second horizontal direction (Y direction). The plurality of contact plugs 152 may be spaced apart from the centers of the plurality of bit line heads BLH, respectively, in the second horizontal direction (Y direction) by the same gap. For example, the central axis of the contact plug 152 may be spaced apart from the center of the bit line head BLH to fall outside of a central one-third of the bit line head BLH.

In one embodiment, one of the bit lines (i.e., one of the bit line heads BLH) includes first and third bit line sidewalls SW1 and SW3 extending in the first horizontal direction, the contact plug 152 includes a central axis in the vertical direction, and the central axis is spaced apart from the first bit line sidewall SW1 by a first gap G1, and the central axis is spaced apart from the third bit line sidewall SW3 by a second gap G2, and the first gap G1 is different from the second gap G2. Likewise, the other one of the bit lines includes second and fourth bit line sidewalls SW2 and SW4 extending in the first horizontal direction, the contact plug 152 includes a central axis in the vertical direction, and the central axis is spaced apart from the second bit line sidewall SW2 by the first gap G1, and the central axis is spaced apart from the fourth bit line sidewall SW4 by the second gap G2.

Referring to FIGS. 4A and 4B, each of the plurality of contact plugs 152 may include a first sidewall S1 and a second sidewall S2. The first sidewall S1 of the contact plug 152 may protrude from the sidewall of the bit line head BLH connected to the contact plug 152 in the second horizontal direction (Y direction). In other words, the contact plug 152 itself protrudes as much as the first sidewall S1 from the sidewall of the bit line head BLH. The contact plug 152 may overlap at least a portion of the insulating spacer 146 in the vertical direction (Z direction). The second sidewall S2 of the contact plug 152 may contact the bit line head BLH and the insulating capping pattern 138B. In one embodiment, the contact plugs 152 may be considered to have a single continuous sidewall, for example that forms a circumference of the contact plugs 152. In this case, a first portion of a sidewall of the contact plug 152 may protrude from the sidewall of the bit line head BLH in the second horizontal direction (Y direction). The contact plug 152 may overlap at least a portion of the insulating spacer 146 in the vertical direction (Z direction). A second portion of the sidewall of the contact plug 152 may contact the bit line head BLH and the insulating capping pattern 138B. Accordingly, it should be appreciated that the term “first sidewall of the contact plug,” “second sidewall of the contact plug” and “third sidewall of the contact plug” in the specification may be interpreted to include the meaning of “first vertical segment of a square shape of a contact plug in a cross sectional view,” “second vertical segment of a square shape of a contact plug in a cross sectional view” and “third vertical segment of a square shape of a contact plug in a cross sectional view,” respectively.

In FIG. 4B, the contact plug 152 is shown to overlap at least a portion of the insulating spacer 146 in the vertical direction (Z direction), but is not limited thereto. For example, the contact plug 152 may entirely overlap the insulating spacer 146 in the vertical direction (Z direction). The first sidewall S1 of the contact plug 152 may be in contact with the conductive dummy plug 140PD, the dummy metal silicide film 172D, and the dummy landing pad 176D.

The contact pad 154 may be placed on the contact plug 152. The contact pad 154 may extend lengthwise in the first horizontal direction (X direction) on the contact plug 152. The contact pad 154 may include or be formed of W, but is not limited thereto.

The contact pad 154 may be spaced apart from the center of the bit line head BLH in the second horizontal direction (Y direction) by a certain gap in the second horizontal direction (Y direction). For example, the contact pad 154 may be spaced apart from the center of the bit line head BLH in the second horizontal direction (Y direction) by a gap of about 5 nm in the second horizontal direction (Y direction). The plurality of contact pads 154 may be spaced apart from the centers of the bit line heads BLH, respectively, in the second horizontal direction (Y direction) by the same gap.

The central axis of the contact pad 154 in the second horizontal direction (Y direction) may be the same as the central axis of the contact plug 152 in the second horizontal direction (Y direction). That is, the contact plug 152 and the contact pad 154 may be spaced apart from the center of the bit line head BLH in the second horizontal direction (Y direction) by the same gap.

Referring to FIGS. 4A and 4B, the width of the contact pad 154 in the second horizontal direction (Y direction) may be less than the width of the bit line head BLH in the second horizontal direction (Y direction), but is not limited thereto. For example, the width of the bit line head BLH in the second horizontal direction (Y direction) may be less than the width of the contact pad 154 in the second horizontal direction (Y direction). In one embodiment the dummy pattern DP may contact one of the contact pads 154 as described in the FIG. 4B. Accordingly, the dummy pattern DP may be electrically connected to one of contact plugs 152. In one embodiment the dummy pattern DP may physically contact one of the contact plug 154.

Conventionally, contact plugs and contact pads were arranged at the center of the bit line head in the second horizontal direction (Y direction). In this case, when the size of the contact pad unfavorably and indeliberately increases during the manufacturing process, bridges (i.e., unfavorable electrical connection) may occur between the contact pads and a dummy landing pad. Additionally, bridges may occur between contact plugs and a dummy landing pad.

In some embodiments, the position of the contact plug 152 and the contact pad 154 are intentionally biased toward one side at a certain gap in the second horizontal direction (Y direction) in the integrated circuit device 100 of the inventive concept. By arranging the contact plug 152 and the contact pad 154 to be intentionally biased, the occurrence of bridges may be reduced.

One of a pair of the contact pads 154 may become closer to the dummy landing pad 176D, but the other one of the pair of the contact pads 154 may be further away from the dummy landing pad 176D. As a result, the occurrence of bridges between the two contact pads 154 arranged on both sides of the dummy landing pad 176D (in the second horizontal direction) may be reduced.

Likewise, one of a pair of the contact plugs 152 may become closer to the dummy landing pad 176D, but the other one of the pair of the contact plugs 152 may be further away from the dummy landing pad 176D. As a result, the occurrence of bridges between the two contact plugs 152 arranged on both sides of the dummy landing pad 176D (in the second horizontal direction) may be reduced.

Additionally, the bridge may be reduced by arranging the contact plug 152 and the contact pad 154 to be biased to one side in some embodiments, so as to increase the design autonomy of the bit line head BLH. That is, by arranging the contact plug 152 and the contact pad 154 to be biased to one side, the width of the bit line head BLH in the second horizontal direction (Y direction) may be designed to be narrower than in the prior art. For example, the width of the bit line head BLH in the second horizontal direction (Y direction) may be designed to be within about 16.5 nm.

Spatially relative terms, such as “spaced apart from,” “protrude from,” “less than a width of,” greater than a width of,” “gap,” and “offset” may be used herein for description to describe one element's or feature's relationship to another element(s) or feature(s) as illustrated in the figures. It should be appreciated that the spatial relationship, which defined by using the spatially relative terms, is intentional or deliberate, unless the context clearly indicates otherwise. That is, the terms mean “spaced apart from something by design,” “protrude from something by design,” “less than a width of something by design,” “greater than a width of something by design,” “gap made by design,” and “offset made by design.” The terms are not used to include any spatial relationship made by accident, intentionally or deliberately. For an example, a semiconductor manufacturing process has allowance which often may be acceptable by a manufacturer, and any spatial relationship resulted from the acceptance of the allowance is excluded from the scope of claims described by the relative terms herein. That is, any unintentional misalignment, which is accepted by anyone during a photolithography process, is excluded from the spatial relationship defined by “spaced apart from” in claims herein. For another example, patterns having the same shape and dimension by design in a photo mask may often result in features having deferent shape and/or dimension in a wafer even by a single photolithography process. This dimensional variation phenomenon (may called as ‘proximity effect’ in industry) is due to the difference of pattern density in the vicinity of the each of the features. Accordingly, any spatial relationship, which is unintentional or indeliberately resulted from the dimensional variation phenomenon, should not be included from the scope of claims described by the relative terms herein. It should be appreciated that the spatial relationship, which defined by using “gap”, is a shortest distance between to elements.

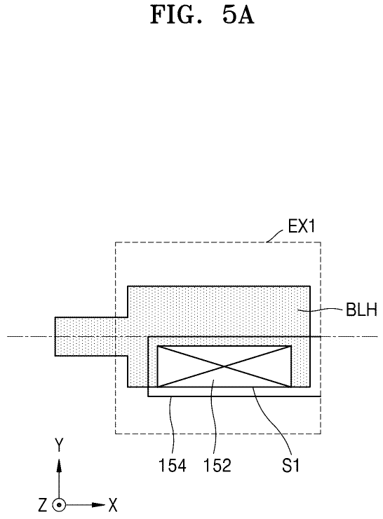

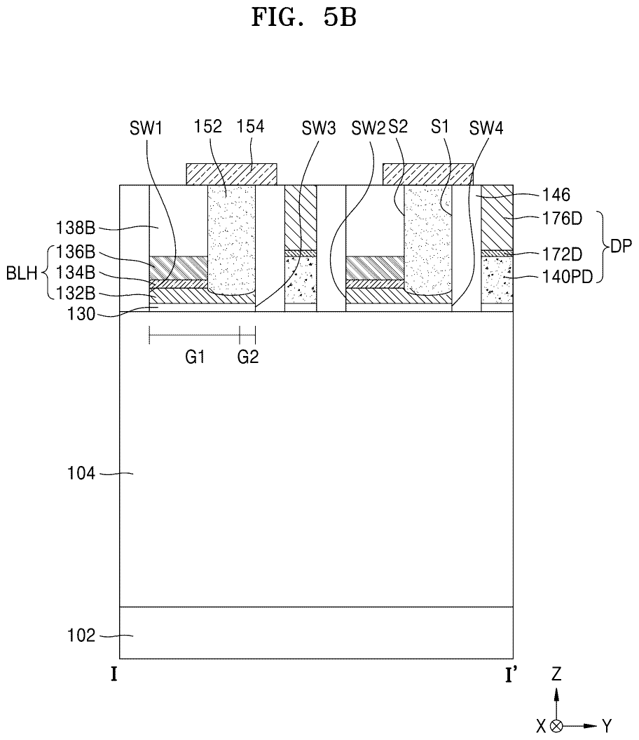

FIG. 5A is an enlarged cross-sectional view of a portion indicated by “EX1” in FIG. 2 according to an embodiment.

FIG. 5B is a cross-sectional view, showing some components, taken along line I-I′ of FIG. 2 according to an embodiment. Hereinafter, descriptions of parts that are in common with those described with reference to FIGS. 4A and 4B are omitted and the differences are mainly described.

Referring to FIGS. 5A and 5B, the contact plug 152 may contact a portion of the bit line head BLH. The contact plug 152 may have a column shape extending in the vertical direction (Z direction) so as to contact a portion of the bit line head BLH. The width of the contact plug 152 in the second horizontal direction (Y direction) may be less than the width of the bit line head BLH in the second horizontal direction (Y direction). The contact plug 152 may penetrate the insulating capping pattern 138B.

The contact plug 152 may be spaced apart from the center of the bit line head BLH in the second horizontal direction (Y direction) by a certain gap in the second horizontal direction (Y direction). The plurality of contact plugs 152 may be spaced apart from the centers of the plurality of bit line heads BLH, respectively, in the second horizontal direction (Y direction) by the same gap.

Referring to FIGS. 5A and 5B, each of the plurality of contact plugs 152 may include a first sidewall S1 and a second sidewall S2. The first sidewall S1 of the contact plug 152 may be coplanar with the sidewall of the bit line head BLH connected to the contact plug 152 in the vertical direction (Z direction). The first sidewall S1 of the contact plug 152 may be in contact with the sidewall of the insulating spacer 146. The second sidewall S2 of the contact plug 152 may contact the bit line head BLH and the insulating capping pattern 138B. Dummy patterns DP may be positioned between a plurality of insulating spacers 146.

The contact pad 154 may be placed on the contact plug 152. The contact pad 154 may extend longitudinally in the first horizontal direction (X direction) on the contact plug 152.

The contact pad 154 may be spaced apart from the center of the bit line head BLH in the second horizontal direction (Y direction) by a certain gap in the second horizontal direction (Y direction). The plurality of contact pads 154 may be spaced apart from the centers of the bit line heads BLH, respectively, in the second horizontal direction (Y direction) by the same gap.

The central axis of the contact pad 154 in the second horizontal direction (Y direction) may be the same as the central axis of corresponding contact plug 152 in the second horizontal direction (Y direction). That is, the contact plug 152 and a corresponding contact pad 154 may be spaced apart from the center of the bit line head BLH in the second horizontal direction (Y direction) by the same gap.

In other words, one of the bit lines (i.e., the bit line heads BLH) includes first and third bit line sidewalls SW1 and SW3 extending in the first horizontal direction, the contact plug 152 includes a central axis in the vertical direction, and the central axis is spaced apart from the first bit line sidewall SW1 by a first gap G1, and the central axis is spaced apart from the third bit line sidewall SW3 by a second gap G2, and the first gap G1 is different than the second gap G2. Likewise, the other one of the bit lines includes second and fourth bit line sidewalls SW2 and SW4 extending in the first horizontal direction, the contact plug 152 includes a central axis in the vertical direction, and the central axis is spaced apart from the second bit line sidewall SW2 by the first gap G1, and the central axis is spaced apart from the fourth bit line sidewall SW4 by the second gap G2. Additionally, a first portion S1 of the sidewall of the contact plug 152 is aligned with the fourth bit line sidewall SW4 or the third bit line sidewall SW3.

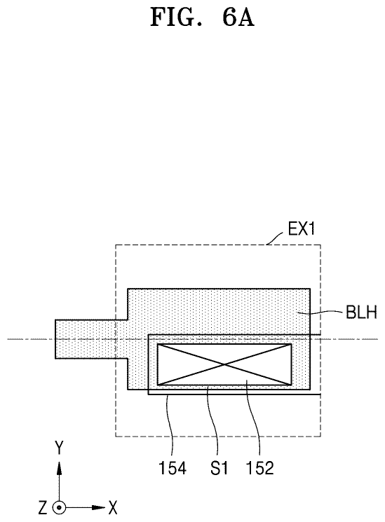

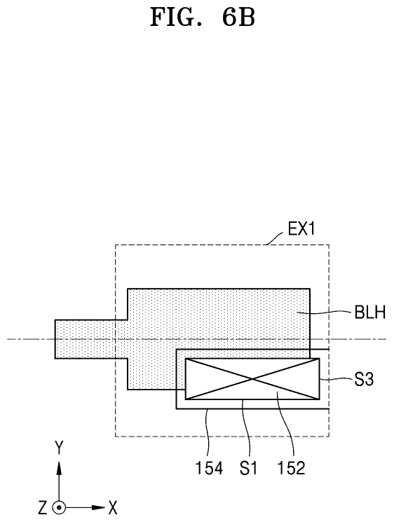

FIGS. 6A and 6B are enlarged cross-sectional views of a portion indicated by “EX1” in FIG. 2 according to an embodiment.

Referring to FIG. 6A, the contact plug 152 may be spaced apart from the center of the bit line head BLH in the second horizontal direction (Y direction) by a certain gap in the second horizontal direction (Y direction). The sidewall of the bit line head BLH may protrude from the first sidewall S1 of the contact plug 152 in the second horizontal direction (Y direction). A certain gap may be formed between the first sidewall S1 of the contact plug 152 and the sidewall of the bit line head BLH.

The contact pad 154 may be spaced apart from the center of the bit line head BLH in the second horizontal direction (Y direction) by a certain gap in the second horizontal direction (Y direction). The central axis of the contact pad 154 in the second horizontal direction (Y direction) may be the same as the central axis of the contact plug 152 in the second horizontal direction (Y direction). That is, the contact plug 152 and the contact pad 154 may be spaced apart from the center of the bit line head BLH in the second horizontal direction (Y direction) by the same gap.

Referring to FIG. 6B, the contact plug 152 may be spaced at a certain gap from the center of the bit line head BLH in the first horizontal direction (X direction) and the second horizontal direction (Y direction). From a plan view, the contact plug 152 may protrude from the bit line head BLH in the first horizontal direction (X direction) and the second horizontal direction (Y direction), but is not limited thereto. At least a portion of the sidewalls of the contact plug 152 may contact the sidewalls of the bit line head BLH. Additionally, the contact plug 152 may form a certain gap between the sidewalls of the contact plug 152 and the sidewalls of the bit line head BLH.

The contact pad 154 may be spaced at a certain gap from the center of the bit line head BLH in the first horizontal direction (X direction) and the second horizontal direction (Y direction). The contact plug 152 and the contact pad 154 may be spaced at an equal gap from the center of the bit line head BLH in the first horizontal direction (X direction) and the second horizontal direction (Y direction).

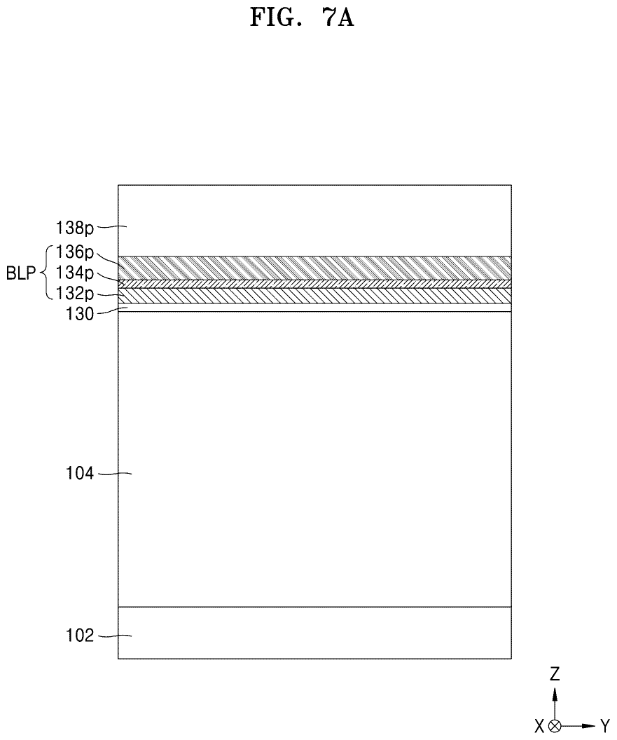

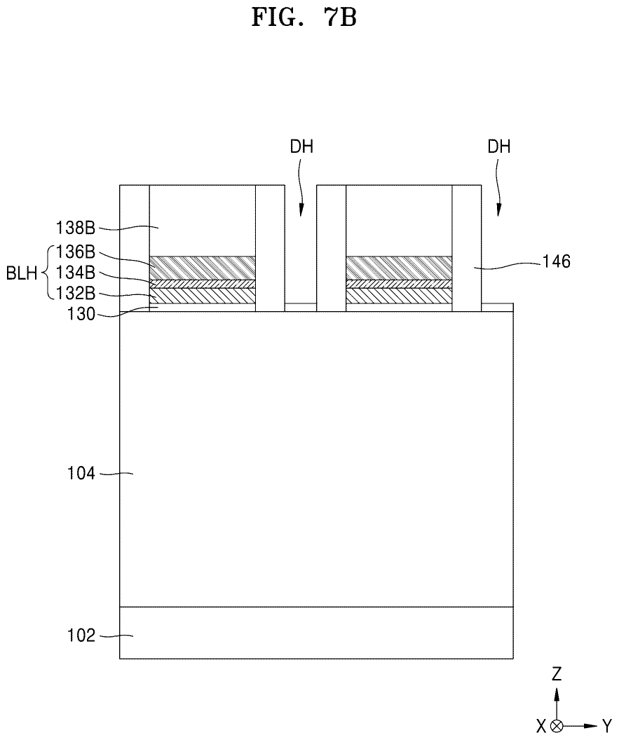

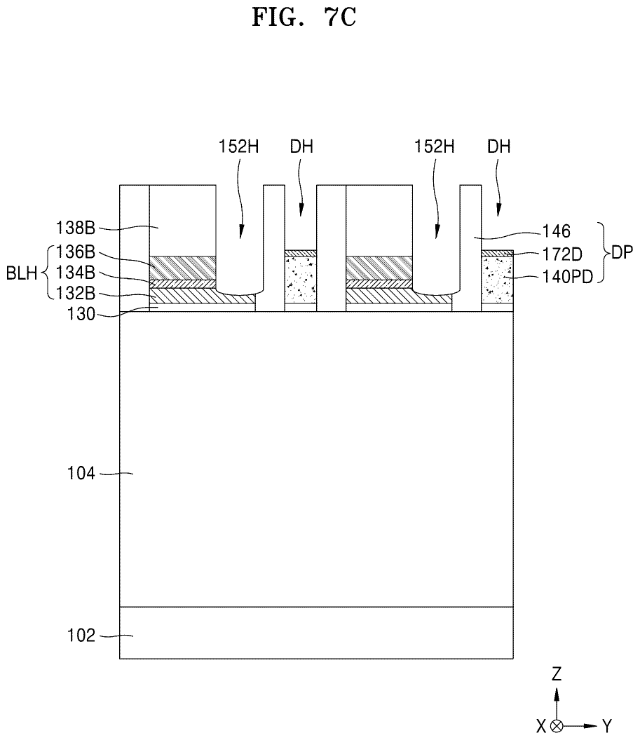

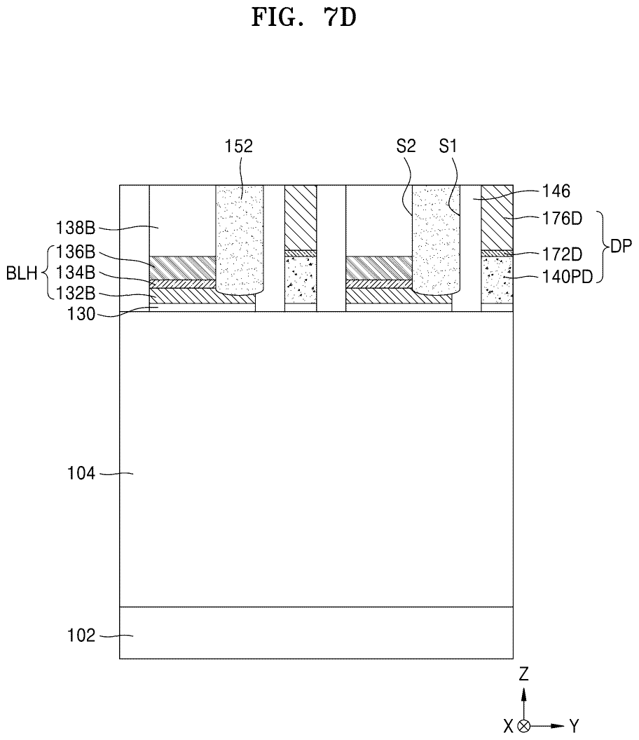

FIGS. 7A to 7D are cross-sectional views, shown according to a process sequence, of a method of manufacturing an integrated circuit device according to an embodiment, and cross-sectional views, shown according to a process sequence, of portions corresponding to a cross-section taken along line I-I′ of FIG. 2.

Referring to FIG. 7A, the device isolation film 104 is defined on the substrate 102, and the device isolation film 104 may be covered by the buffer insulating film 130. The buffer insulating film 130 may include an oxide film, a nitride film, or a combination thereof.

A preliminary bit line head BLP may be positioned on the buffer insulating film 130. The preliminary bit line head BLP may extend in the first horizontal direction (X direction). The preliminary bit line head BLP may include a preliminary lower conductive layer 132p, a preliminary intermediate conductive layer 134p, and a preliminary upper conductive layer 136p which are sequentially formed on the buffer insulating film 130. An insulating capping pattern 138p may be formed on the preliminary upper conductive layer 136p.

Referring to FIG. 7B, portions of the preliminary bit line head BLP may be removed to form dummy holes DH. By forming the dummy holes DH, a plurality of bit line heads BLH may be formed. The plurality of bit line heads BLH may be arranged parallel to each other in the second horizontal direction (Y direction). The plurality of bit line heads BLH may extend in the first horizontal direction (X direction).

Thereafter, each of the plurality of insulating spacers 146 may cover the sidewall of the bit line head BLH. The plurality of insulating spacers 146 may extend longitudinally in the first horizontal direction (X direction) parallel to the plurality of bit line heads BLH on both sidewalls of the plurality of bit heads BLH. The plurality of insulating spacers 146 may include an oxide film, a nitride film, an air spacer, or a combination thereof.

Referring to FIG. 7C, the plurality of conductive dummy plugs 140PD may fill portions of the dummy holes DH. The plurality of conductive dummy plugs 140PD may include doped polysilicon, metal, conductive metal nitride, or a combination thereof. The plurality of conductive dummy plugs 140PD may be substantially the same as the plurality of buried contacts BC (see FIG. 2) in the cell array area MCA.

The dummy metal silicide films 172D may be formed on the plurality of conductive dummy plugs 140PD. The dummy metal silicide films 172D may be formed through a silicide process. The dummy metal silicide films 172D may include cobalt silicide, nickel silicide, or manganese silicide.

Thereafter, a plurality of direct contact holes 152H may be formed. The plurality of direct contact holes 152H may be formed by removing portions of the bit line heads BLH. The plurality of direct contact holes 152H may have a column shape extending in the vertical direction (Z direction) by removing portions of the bit line heads BLH. The width of the plurality of direct contact holes 152H in the second horizontal direction (Y direction) may be less than the width of the bit line head BLH in the second horizontal direction (Y direction). The plurality of direct contact holes 152H may penetrate the insulating capping pattern 138B.

The plurality of direct contact holes 152H may be spaced apart from the centers of the bit line heads BLH in the second horizontal direction (Y direction) by a certain gap in the second horizontal direction (Y direction). For example, the plurality of direct contact holes 152H may be spaced apart from the centers of the bit line heads BLH in the second horizontal direction (Y direction) by a gap of about 5 nm in the second horizontal direction (Y direction) The plurality of direct contact holes 152H may be spaced apart from centers of the plurality of bit line heads BLH in the second horizontal direction (Y direction) by the same gap.

Each of the plurality of direct contact holes 152H may protrude in the second horizontal direction (Y direction) from the sidewall of the bit line head BLH. Each of the plurality of direct contact holes 152H may overlap at least a portion of the insulating spacer 146 in the vertical direction (Z direction).

Referring to FIG. 7D, the plurality of contact plugs 152 may fill the plurality of direct contact holes 152H. In addition, the plurality of dummy landing pads 176D filling the plurality of dummy holes DH may be formed. The top surfaces of the plurality of contact plugs 152, the plurality of dummy landing pads 176D, and the insulating capping pattern 138B may be on the same level. The plurality of contact plugs 152 and the plurality of dummy landing pads 176D may include a metal-containing material such as W, but are not limited thereto.

Thereafter, referring back to FIG. 4B, the plurality of contact pads 154 may be formed on the plurality of contact plugs 152. The plurality of contact plugs 152 may be electrically connected to the plurality of contact pads 154.

As used herein, “contact plug” may refer, for example, to an electrically conductive structure filled within a contact hole (or a via), unless the context clearly indicates otherwise. As used herein, “contact pad” may refer, for example, to an electrically conductive structure formed directly on the “contact plug” and outside of the contact hole (or via), unless the context clearly indicates otherwise. In some case, a contact plug and a contact pad may be in form of continuously integrated structure, without a discontinuous boundary surface therebetween. However, it should be appreciated that a portion of the continuously integrated structure within a contact hole (or a via) is interpreted as a contact plug and the other portion of the continuously integrated structure outside of the contact hole (or via) is interpreted as a contact pad.

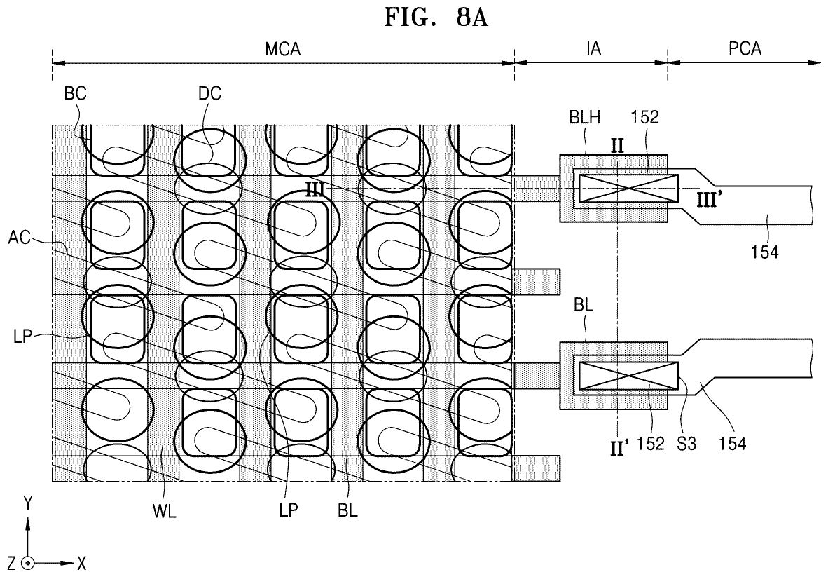

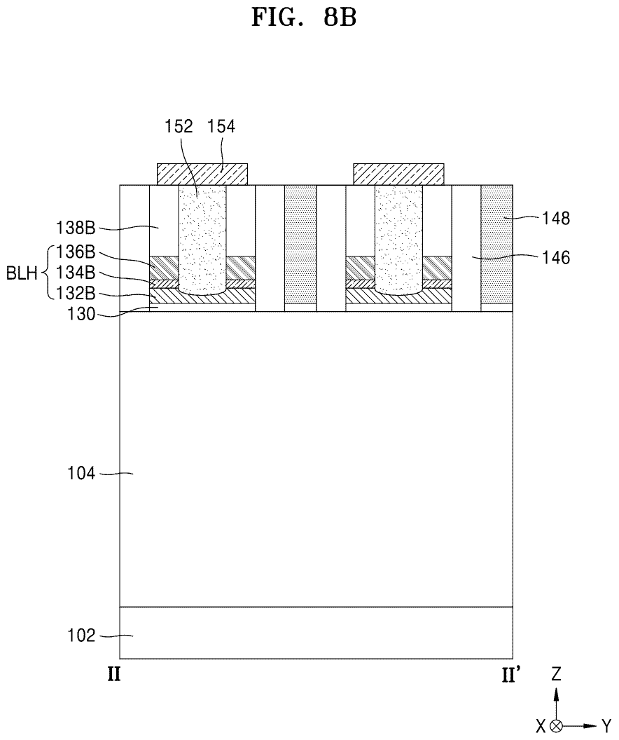

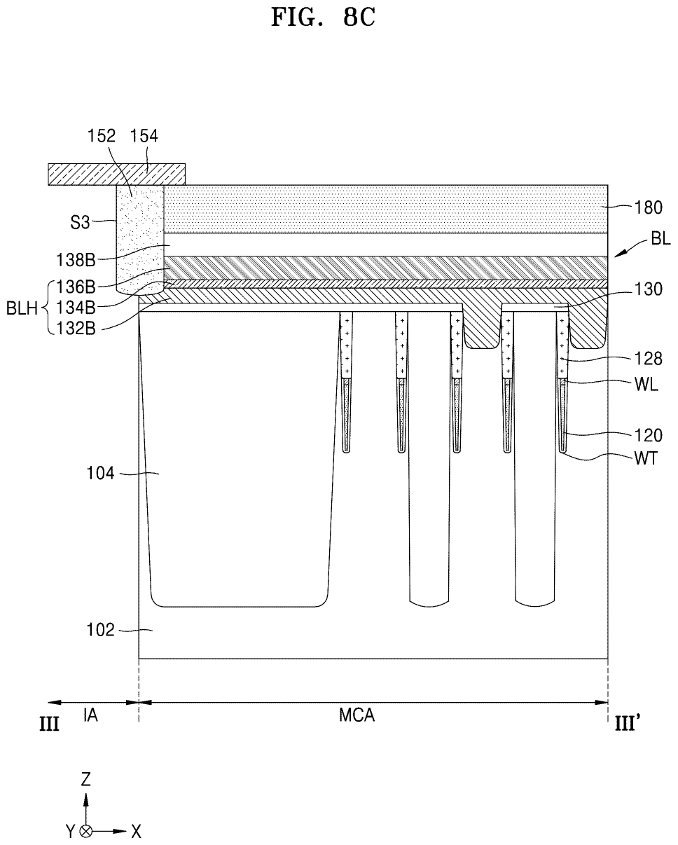

FIG. 8A is an enlarged layout diagram of portion A of FIG. 1 according to an embodiment.

FIG. 8B is a cross-sectional view, showing some components, taken along line II-II′ of FIG. 8A.

FIG. 8C is a cross-sectional view, showing some components, taken along line III-III′ of FIG. 8A. Hereinafter, descriptions of parts that are in common with those described with reference to FIGS. 1 and 6B are omitted and the differences are mainly described.

Referring to FIGS. 8A to 8C, the contact plugs 152 and the contact pads 154 may be placed in the interface area IA of the integrated circuit device 100 (see FIG. 1). The contact plugs 152 and the contact pads 154 may include or be formed of W, but are not limited thereto.

The contact plug 152 may be connected to the bit line head BLH. The bit line head BLH may be formed at one end portion of the bit line BL extending to the interface area IA. From a plan view, the bit line head BLH may have a hammer-head shape. The width of the bit line head BLH in the second horizontal direction (Y direction) may be greater than the width of the bit line BL in the second horizontal direction (Y direction).

The contact plug 152 may be spaced apart from the center of the bit line head BLH by a certain gap in the first horizontal direction (X direction). Each of the plurality of contact plugs 152 may be spaced apart from the center of each of the plurality of bit line heads BLH in the first horizontal direction (X direction) by the same gap.

A third sidewall S3 of the contact plug 152 in the first horizontal direction (X direction) may protrude from the sidewall of the bit line head BLH, but is not limited thereto. The third sidewall S3 of the contact plug 152 may be coplanar with the sidewall of the bit line head BLH.

The contact plug 152 may be electrically connected to one end portion of the contact pad 154. The contact pad 154 may extend to the peripheral circuit area PCA in the first horizontal direction (X direction). The contact plug 152 may electrically connect the bit line BL in the cell array area MCA and the contact pad 154 in the peripheral circuit area PCA.

In some embodiments, the contact plug 152 may contact a portion of the bit line head BLH. The contact plug 152 may have a column shape extending in the vertical direction (Z direction) so as to contact a portion of the bit line head BLH.

The contact plug 152 may be positioned at the center of the bit line head BLH in the second horizontal direction (Y direction). The width of the contact plug 152 in the second horizontal direction (Y direction) may be less than the width of the bit line head BLH in the second horizontal direction (Y direction).

The contact pad 154 may be placed on the contact plug 152. The contact pad 154 may be placed at the center of the bit line head BLH in the second horizontal direction (Y direction) on the contact plug 152. The central axis of the contact pad 154 in the second horizontal direction (Y direction) may be the same as the central axis of the contact plug 152 in the second horizontal direction (Y direction). The contact pad 154 may include or be formed of W, but is not limited thereto.

The contact pad 154 may be spaced apart from the center of the bit line head BLH by a certain gap in the first horizontal direction (X direction). Each of the plurality of contact pads 154 may be spaced apart from the center of each of the plurality of bit line heads BLH in the first horizontal direction (X direction) by the same gap.

Sidewalls of the plurality of bit line heads BLH may be covered by the plurality of insulating spacers 146, respectively. The plurality of insulating spacers 146 may extend longitudinally in the first horizontal direction (X direction) parallel to the plurality of bit line heads BLH on both sidewalls of the plurality of bit heads BLH. The plurality of insulating spacers 146 may include an oxide film, a nitride film, an air spacer, or a combination thereof.

In some embodiments, an insulative dummy pattern 148 may be placed in a space between each of the plurality of insulating spacers 146. In this case, the insulative dummy pattern 148 is electrically insulative. That is, the insulative dummy pattern 148 may include or be formed of electrically insulative material like an oxide film, a nitride film, or a combination thereof.

In some embodiments, by placing the insulative dummy pattern 148 between two adjacent contact plugs 152, the occurrence of bridges between the two contact plugs 152 may be reduced. In addition, by placing the insulative dummy pattern 148 between two adjacent contact pads 154, the occurrence of bridges between the two adjacent contact pads 154 may be reduced.

In addition, by arranging the portion S3 of the sidewall of the contact plug 152 to protrude from the sidewall of the bit line head BLH in the first horizontal direction (X direction), a gap between a core and a periphery in view of core-peri reduction (CPR) may be reduced. As a result, there is an effect of improving the degree of integration of integrated circuit devices.

While the inventive concept has been particularly shown and described with reference to embodiments thereof, it will be understood that various changes in form and details may be made therein without departing from the spirit and scope of the following claims.

Although the figures described herein may be referred to using language such as “an embodiment,” “some embodiment,” or “certain embodiments,” these figures, and their corresponding descriptions are not intended to be mutually exclusive from other figures or descriptions, unless the context so indicates. Therefore, certain aspects from certain figures may be the same as certain features in other figures, and/or certain figures may be different representations or different portions of a particular exemplary embodiment.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

What is claimed is:

1. An integrated circuit device comprising:
a substrate having a cell array area including a plurality of unit memory cells;
a peripheral circuit area surrounding the cell array area;
an interface area between the cell array area and the peripheral circuit area;
first and second bit lines extending in a first horizontal direction, each of the first and second bit lines connected to a respective set of the unit memory cells in the cell array area, the first bit line including a first end portion in the interface area, and the second bit line including a second end portion in the interface area; and
first and second contact plugs in the interface area, the first contact plug contacting the first end portion, and the second contact plug contacting the second end portion,
wherein the first bit line includes first and third bit line sidewalls extending in the first horizontal direction, the second bit line includes second and fourth bit line sidewalls extending in the first horizontal direction, the third bit line sidewall is closer than the first bit line sidewall to the first contact plug in a second horizontal direction which is perpendicular to the first horizontal direction, and the second bit line sidewall is closer than the fourth bit line sidewall to the second contact plug in the second horizontal direction,
wherein the first contact plug includes a first central axis in a vertical direction which is perpendicular to both the first and second horizontal direction, and the second contact plug includes a second central axis in the vertical direction,
wherein the first central axis is spaced apart from the first bit line sidewall by a first gap, the first central axis is spaced apart from the third bit line sidewall by a second gap, and the first gap is different from the second gap, and
wherein the second central axis is spaced apart from the second bit line sidewall by the first gap, and the second central axis is spaced apart from the fourth bit line sidewall by the second gap.

2. The integrated circuit device of claim 1, wherein each of the first and second end portions is wider in the second horizontal direction than another portion of the first and second bit lines in the cell array area.

3. The integrated circuit device of claim 1, further comprising:
a first contact pad formed on the first contact plug; and
a second contact pad formed on the second contact plug,
wherein each of the first and second end portions is wider in the second horizontal direction than each of the first and second contact pads.

4. The integrated circuit device of claim 3, each of the first and second end portions has a hammer-head shape.

5. The integrated circuit device of claim 1, wherein the first contact plug includes a first contact plug sidewall, and the second contact plug includes a second contact plug sidewall, and
wherein a portion of the first contact plug protrudes in the second horizontal direction from one of the first and third bit line sidewalls, a portion of the second contact plug protrudes in the second horizontal direction from one of the second and fourth bit line sidewalls.

6. The integrated circuit device of claim 1, wherein the first contact plug includes a first contact plug sidewall, and the second contact plug includes a second contact plug sidewall, and
wherein a portion of the first contact plug sidewall is aligned with one of the first and third bit line sidewalls, and a portion of the second contact plug sidewall is aligned with one of the second and fourth bit line sidewalls.

7. The integrated circuit device of claim 1, further comprising a dummy pattern,
wherein the dummy pattern is positioned between the first and second contact plugs,
wherein the dummy pattern is electrically isolated, and
wherein the dummy pattern has electrical conductivity.

8. The integrated circuit device of claim 1, further comprising a dummy pattern,
wherein the dummy pattern is positioned between the first and second contact plugs,
wherein the dummy pattern is electrically connected to one of the first and second contact plugs, and
wherein the dummy pattern has electrical conductivity.

9. The integrated circuit device of claim 1, further comprising:
a first contact pad formed on the first contact plug; and
a second contact pad formed on the second contact plug,
wherein the first contact pad includes a third central axis in the vertical direction, and the second contact pad includes a fourth central axis in the vertical direction,
wherein the third central axis is spaced apart from the first bit line sidewall by a third gap, the third central axis is spaced apart from the third bit line sidewall by a fourth gap, and the third gap is different from the fourth gap, and
wherein the fourth central axis is spaced apart from the second bit line sidewall by the third gap, and the fourth central axis is spaced apart from the fourth bit line sidewall by the fourth gap.

10. The integrated circuit device of claim 9, further comprising a dummy pattern,
wherein the dummy pattern is positioned between the first and second contact plugs, and
wherein the dummy pattern is electrically connected to one of the first and second contact plugs.

11. The integrated circuit device of claim 9, wherein the first central axis is the same as the third central axis, and the second central axis is the same as the fourth central axis.

12. The integrated circuit device of claim 1, further comprising a third bit line connected to another portion of the unit memory cells in the cell array area,
wherein third bit line extends in the first horizontal direction, and
wherein the third bit line is positioned between the first and second bit lines.

13. An integrated circuit device comprising:
a substrate having a cell array area including a plurality of unit memory cells;
a peripheral circuit area surrounding the cell array area;
an interface area between the cell array area and the peripheral circuit area;
first and second bit lines extending in a first horizontal direction, each of the first and second bit lines connected to a respective set of the unit memory cells in the cell array area, the first bit line including a first end portion in the interface area, and the second bit line including a second end portion in the interface area; and
first and second contact plugs in the interface area, the first contact plug contacting the first end portion, and the second contact plug contacting to the second end portion,
wherein the first bit line includes first and third bit line sidewalls extending in the first horizontal direction, the second bit line includes second and fourth bit line sidewalls extending in the first horizontal direction, the third bit line sidewall is closer than the first bit line sidewall to the first contact plug in a second horizontal direction which is perpendicular to the first horizontal direction, and the second bit line sidewall is closer than the fourth bit line sidewall to the second contact plug in the second horizontal direction,
wherein the first contact plug includes a first contact plug sidewall, and the second contact plug includes a second contact plug sidewall, and
wherein a portion of the first contact plug sidewall protrudes in the second horizontal direction from one of the first and third bit line sidewalls, and a portion of the second contact plug sidewall protrudes in the second horizontal direction from one of the second and fourth bit line sidewalls.

14. The integrated circuit device of claim 13, further comprising a third bit line connected to another portion of the unit memory cells in the cell array area,
wherein third bit line extends in the first horizontal direction, and
wherein the third bit line is positioned between the first and second bit lines.

15. The integrated circuit device of claim 13, further comprising:
a first contact pad formed on the first contact plug; and
a second contact pad formed on the second contact plug,
wherein the first contact plug includes a first central axis in a vertical direction which is perpendicular to both the first and second horizontal direction, and the second contact plug includes a second central axis in the vertical direction,
wherein the first contact pad includes a third central axis in the vertical direction, and the second contact pad includes a fourth central axis in the vertical direction, and
wherein the first central axis is aligned with the third central axis, and the second central axis is the same as the fourth central axis.

16. The integrated circuit device of claim 15, further comprising a dummy pattern,
wherein the dummy pattern is positioned between the first and second contact plugs,
wherein the dummy pattern has electrically conductivity, and
wherein the dummy pattern electrically contacts one of the first and second contact plugs.

17. An integrated circuit device comprising:
a substrate having a cell array area including a plurality of unit memory cells;
a peripheral circuit area surrounding the cell array area;
an interface area between the cell array area and the peripheral circuit area;
first and second bit lines extending in a first horizontal direction, each of the first and second bit lines connected to a respective set of the unit memory cells in the cell array area, the first bit line including a first end portion in the interface area, and the second bit line including a second end portion in the interface area;
first and second contact plugs in the interface area, the first contact plug contacting the first end portion, and the second contact plug contacting to the second end portion;
a first contact pad formed on the first contact plug;
a second contact pad formed on the second contact plug; and
a dummy pattern positioned between the first and second contact plugs,
wherein the dummy pattern is formed of electrically insulative material, and
wherein the dummy pattern contacts one of the first and second contact pads.

18. The integrated circuit device of claim 17, wherein the first bit line includes first and third bit line sidewalls extending in the first horizontal direction, the second bit line includes second and fourth bit line sidewalls extending in the first horizontal direction, the third bit line sidewall is closer than the first bit line sidewall to the first contact plug in a second horizontal direction which is perpendicular to the first horizontal direction, and the second bit line sidewall is closer than the fourth bit line sidewall to the second contact plug than in the second horizontal direction,
wherein the first contact plug includes a first central axis in a vertical direction which is perpendicular to both the first and second horizontal direction, and the second contact plug includes a second central axis in the vertical direction,
wherein the first central axis is spaced apart from the first bit line sidewall by a first gap, the first central axis is spaced apart from the third bit line sidewall by a second gap, and the first gap is different from the second gap, and
wherein the second central axis is spaced apart from the second bit line sidewall by the first gap, and the second central axis is spaced apart from the fourth bit line sidewall by the second gap.

19. The integrated circuit device of claim 18, wherein the first contact pad includes a third central axis in the vertical direction, and the second contact pad includes a fourth central axis in the vertical direction,
wherein the third central axis is spaced apart from the first bit line sidewall by a third gap, the third central axis is spaced apart from the third bit line sidewall by a fourth gap, and the third gap is different from the fourth gap, and
wherein the third central axis is spaced apart from the second bit line sidewall by the third gap, the third central axis is spaced apart from the fourth bit line sidewall by the fourth gap.

20. The integrated circuit device of claim 17, further comprising a third bit line connected to another portion of the unit memory cells in the cell array area,
wherein third bit line extends in the first horizontal direction, and
wherein the third bit line is positioned between the first and second bit lines.
